(19) United States
(12) Patent Application Publication
(10) Pub. No.: US 2025/0098119 A1
(43) Pub. Date: Mar. 20, 2025

(54) CONDUCTOR COOLING STRUCTURE

(71) Applicant: Yazaki Corporation, Tokyo (JP)

(72) Inventors: Kazuki SHIROSAKA, Kakegawa-shi (JP); Junya Higashi, Kakegawa-shi (JP); Hiroyuki Tanaka, Kakegawa-shi (JP)

(73) Assignee: Yazaki Corporation, Tokyo (JP)

(21) Appl. No.: 18/805,903

(22) Filed: Aug. 15, 2024

(30) Foreign Application Priority Data
Sep. 20, 2023 (JP) 2023-152097

(51) Int. Cl. H05K 7/20

(52) U.S. Cl. CPC H05K 7/20454; H05K 7/2049

(57) ABSTRACT

A conductor cooling structure includes a cooling plate formed into a band plate shape made of a conductive metal and being a flat plate like member configured to cool a conductor member with a predetermined electric/electronic component being fixed to a front surface of the cooling plate in such a state that the conductor member is placed on the front surface of the cooling plate, the conductor member configured to be energized with one end side of the conductor member being connected to a component terminal of the electric/electronic component, and the other end side of the conductor member being connected to an electrical connection target of the electric/electronic component, a conductor groove being formed on the front surface of the cooling plate, the conductor groove extending along a shape of a longitudinal direction of the conductor member and formed to have a sufficient depth to accommodate at least a portion of the conductor member in a thickness direction thereof, and a heat transfer member covering an area larger than at least the conductor groove on the front surface of the cooling plate so as to be sandwiched between a groove inner surface of the conductor groove and the conductor member, the heat transfer member being made of an insulating material that transfers heat of the conductor member to the cooling plate.

### TECHNICAL FIELD

The present disclosure relates to a conductor cooling structure for cooling a conductor member that connects component terminals of an electric/electronic component to an electrical connection target.

### BACKGROUND

A conventional cooling structure has been known in which a bottom wall of an apparatus housing serves as a cooling plate to transfer and dissipate heat from conductor members that connects component terminals of an electric/electronic component to an electrical connection target (for example, see Patent Document 1). The cooling structure of Patent Document 1 is designed to transfer heat from the metal conductor members to the cooling plate via an insulating member, so that heat from the conductor member is dissipated while electrical leakage is prevented.

### RELATED ART

### Patent Documents

[Patent Document 1] JP2020127302 A

### SUMMARY OF THE INVENTION

### Problem to be Solved by the Invention

In this case, in the cooling structure of the Patent Document 1 explained above, the heat transfer distance between the conductor members and the cooling plate via the intervening object is long, which tends to result in a low cooling efficiency.

Accordingly, the present disclosure has been made in view of the above-mentioned problems, and it is an object of the present disclosure to provide a conductor cooling structure capable of improving the cooling efficiency for conductor members.

### Solution to Problem

In order to solve the problems explained above, a conductor cooling structure includes a cooling plate formed into a band plate shape made of a conductive metal and being a flat plate like member configured to cool a conductor member with a predetermined electric/electronic component being fixed to a front surface of the cooling plate in such a state that the conductor member is placed on the front surface of the cooling plate, the conductor member configured to be energized with one end side of the conductor member being connected to a component terminal of the electric/electronic component, and the other end side of the conductor member being connected to an electrical connection target of the electric/electronic component, a conductor groove being formed on the front surface of the cooling plate, the conductor groove extending along a shape of a longitudinal direction of the conductor member and formed to have a sufficient depth to accommodate at least a portion of the conductor member in a thickness direction thereof, and a heat transfer member covering an area larger than at least the conductor groove on the front surface of the cooling plate so as to be sandwiched between a groove inner surface of the conductor groove and the conductor member, the heat transfer member being made of an insulating material that transfers heat of the conductor member to the cooling plate.

### Advantageous Effects of the Invention

According to the conductor cooling structure explained above, the cooling efficiency for conductor members can be improved.

### BRIEF DESCRIPTION OF THE DRAWINGS

FIG. 1 is a perspective view illustrating a conductor cooling structure according to one embodiment.

FIG. 2 is an exploded perspective view of the conductor cooling structure illustrated in FIG. 1.

FIG. 3 is a side surface view of the conductor cooling structure as seen from the direction of arrow V11 of FIG. 1.

### DETAILED DESCRIPTION OF THE EXEMPLARY EMBODIMENT

One embodiment of a conductor cooling structure is hereinafter explained.

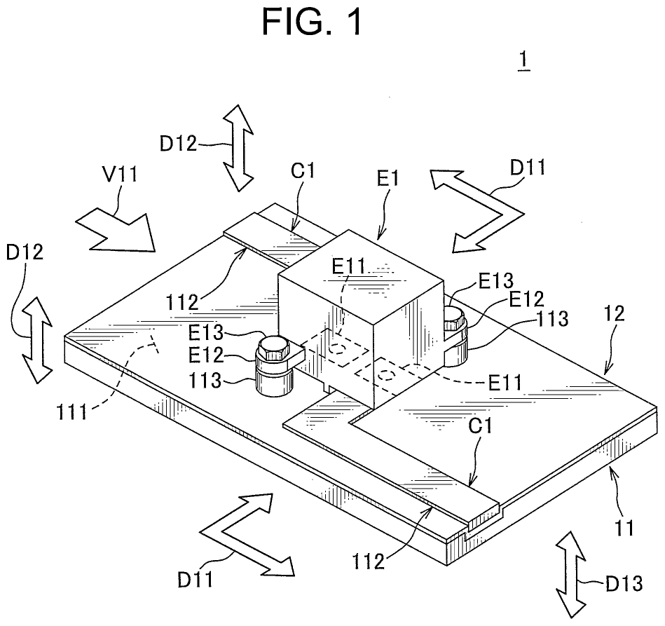

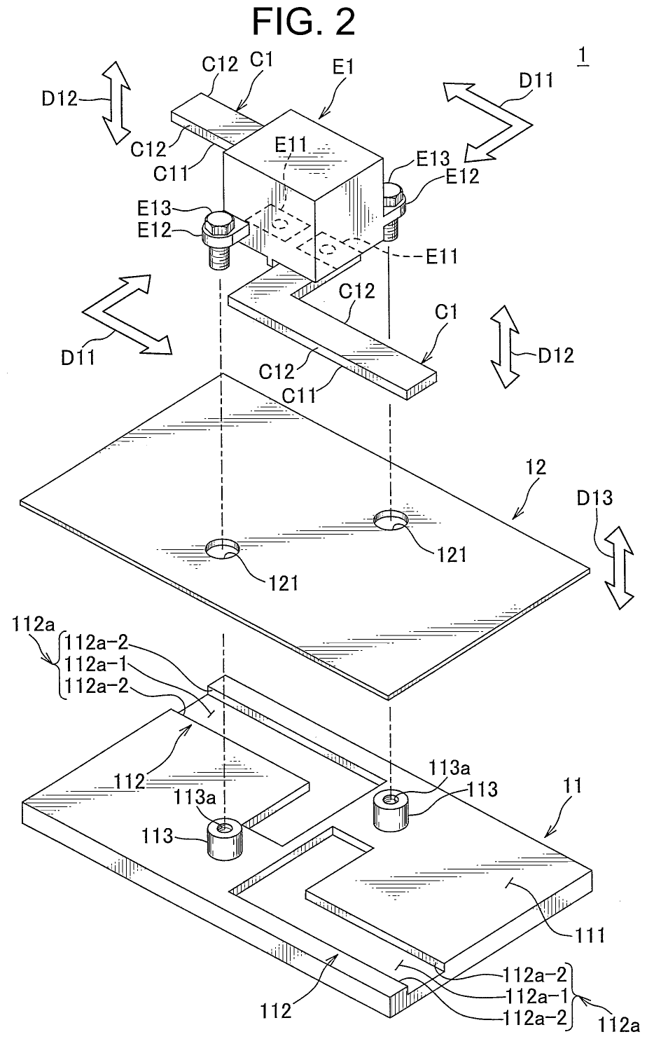

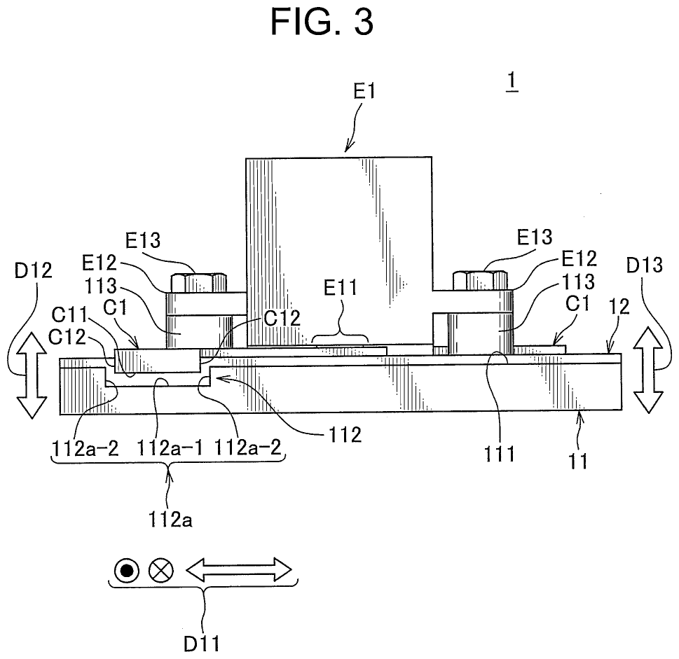

FIG. 1 is a perspective view illustrating a conductor cooling structure 1 according to one embodiment. FIG. 2 is an exploded perspective view of the conductor cooling structure 1 illustrated in FIG. 1. FIG. 3 is a side surface view of the conductor cooling structure 1 as seen from the direction of arrow V11 of FIG. 1.

The conductor cooling structure 1 according to the present embodiment is a structure for cooling conductor members C1 that connect component terminals E11 of a relay, i.e., an electric/electronic component E1, to an electrical connection target of the electric/electronic component E1. The electric/electronic component E1 is provided with the pair of component terminals E11, and the pair of conductor members C1 are provided in one-to-one correspondence with the pair of component terminals E11. Each of the conductor members C1 is made of a conductive metal such as copper and is formed into a band plate in an L shape that is bent 90° along the way, with one end side of each of the conductor members C1 being connected to the component terminal E11 and the other end side being connected to an electrical connection target to form an electrically conductive busbar. The conductor cooling structure 1 for cooling the pair of conductor members C1 includes a cooling plate 11 and a heat transfer member 12 for transferring, to the cooling plate 11, heat generated in the conductor members C1 when energized.

The cooling plate 11 is a flat member for cooling the conductor members C1 when the electric/electronic component E1 is fixed to a front surface 111 of the cooling plate 11 with the pair of conductor members C1 being placed on the front surface 111. A pair of conductor grooves 112 is formed on the front surface 111 of the cooling plate 11, and is aligned in one-to-one correspondence with the shape of a longitudinal direction D11 of the pair of conductor members C1 bent into the L shape. Each of the conductor grooves 112 is formed as an angular groove in an L shape having a depth sufficient to accommodate the conductor member C1 at least partially (approximately half in the present embodiment) in its thickness direction D12.

Furthermore, component fixing studs 113 are provided vertically on the front surface 111 of the cooling plate 11 such that the electric/electronic component E1 of which the component terminals E11 are connected to the respective conductor members C1 is fixed to the component fixing studs 113. The electric/electronic component E1 has a pair of fixing flanges E12 protruding from its outer side surface for screw fastening, and the cooling plate 11 is provided with a pair of component fixing studs 113 in one-to-one correspondence with the pair of fixing flanges E12. With the pair of conductor members C1 being fixed to the electric/electronic component E1, the fixing flanges E12 are placed on the end surfaces of the respective component fixing studs 113. Screws E13 penetrating the fixing flanges E12 are screwed into screw holes 113a of the respective component fixing studs 113, so that the electric/electronic component E1 is fixed to the cooling plate 11 together with the pair of conductor members C1.

The heat transfer member 12 is a flexible sheet material that is placed over the front surface 111 of the cooling plate 11 so as to be sandwiched between the groove inner surfaces 112a of the pair of conductor grooves 112 and the pair of conductor members C1. As an example of this flexible sheet material, a heat transfer sheet such as Tflex SF600 Series (registered trademark) of Laird can be used. Also, in the present embodiment, the heat transfer member 12 is disposed so as to cover the entire surface of the front surface 111 of the cooling plate 11, thereby covering an area wider than the pair of conductor grooves 112 and transferring heat from the pair of conductor members C1 to the cooling plate 11. The heat transfer member 12 also has stud through holes 121 through which the pair of component fixing studs 113 of the cooling plate 11 pass. The electric/electronic component E1 is fixed to the cooling plate 11 by the screw fastening explained above, in such a way that the pair of conductor members C1 are pressed into the pair of conductor grooves 112 with the heat transfer member 12 sandwiched therebetween.

Moreover, the conductor grooves 112 of the cooling plate 11 are wider than the conductor members C1 by an amount corresponding to the thickness of the heat transfer member 12. When the electric/electronic component E1 is fixed by the screw fastening explained above, the portions of the heat transfer member 12 covering the conductor grooves 112 are pushed into the inside of the conductor grooves 112 by the conductor members C1. When the conductor members C1 are pressed against the conductor grooves 112, the heat transfer member 12, i.e., a flexible sheet material, is pressed into the inside of the conductor grooves 112 so as to be crushed in a member thickness direction D13 of the heat transfer member 12. Through this pressing, the heat transfer member 12 is made into a close contact state at the following locations between the groove inner surfaces 112a of the respective conductor grooves 112 and the external surface of the conductor member C1. First, the heat transfer member 12 is sandwiched, in a close contact manner, between a groove bottom surface 112a-1 of the groove inner surface 112a of each of the conductor grooves 112 and a groove opposing surface C11, which is one of the front and back surfaces of the conductor member C1, facing the groove bottom surface 112a-1. Furthermore, the heat transfer member 12 is sandwiched, in a close contact manner, between a pair of opposing groove side surfaces 112a-2 of the groove inner surface 112a and a pair of side edge surfaces C12 of the conductor member C1 extending in the thickness direction D12.

According to the conductor cooling structure 1 explained above, a distance between the conductor member C1 and the cooling plate 11 is kept to a short distance equivalent to the thickness of the heat transfer member 12 inside the conductor grooves 112. Furthermore, since the heat transfer member 12 covers a larger area than the conductor grooves 112, the following locations are cooled by the heat transfer member 12 conducting heat to the cooling plate 11. First, the groove opposing surface C11, which is one of the front and back surfaces of the conductor member C1, on the side of the cooling plate 11 is cooled. Also, in the surface portions of the side edge surfaces C12 of the conductor member C1 that fit within the inside of the conductor groove 112 in the thickness direction D12, heat is transferred by the heat transfer member 12 to the cooling plate 11 to be cooled. In this way, the cooling area extends to the side edge surfaces C12 of the conductor member C1, and furthermore, due to the short distance between the conductor member C1 and the cooling plate 11 as explained above, so that the cooling efficiency for the conductor member C1 can be improved.

In this case, in the present embodiment, the conductor grooves 112 are wider than the conductor members C1 by an amount corresponding to the thickness of the heat transfer member 12. According to this configuration, the heat transfer member 12 is inserted between the side edge surfaces C12 of the conductor member C1 and the groove side surfaces 112a-2 of the conductor groove 112, so that heat can be effectively transferred between the two, thereby further improving the cooling efficiency.

Furthermore, in the present embodiment, the heat transfer member 12 is disposed to cover the entire surface of the front surface 111 of the cooling plate 11. According to this configuration, the heat transfer member 12 does not require fine shape processing and can be effectively interposed between the groove inner surfaces 112a of the conductor groove 112 and the conductor member C1, the manufacturing cost can be reduced accordingly.

Furthermore, in the present embodiment, the component fixing studs 113 are vertically provided on the front surface 111 of the cooling plate 11, and the stud through holes 121 is provided in the heat transfer members 12. Then, when the electric/electronic component E1 is fixed to the cooling plate 11 via the component fixing studs 113, the conductor members C1 are pressed against the conductor grooves 112 with the heat transfer member 12 sandwiched between the conductor members C1 and the groove inner surfaces 112a. According to this configuration, with the fixing of the electric/electronic component E1, the conductor members C1 can be effectively pressed against the conductor grooves 112 of the cooling plate 11 with the heat transfer member 12 sandwiched therebetween, thereby reducing manufacturing costs compared to providing a separate pressing structure for the conductor member C1.

Furthermore, in the present embodiment, the heat transfer member 12 is made of a flexible sheet material, and when the conductor members C1 are pressed against the conductor grooves 112, the heat transfer member 12 comes into close contact with both the groove bottom surfaces 112a-1 and the groove opposing surfaces C11, and also with both the groove side surfaces 112a-2 and the side edge surfaces C12. According to this configuration, by using the flexible sheet material for the heat transfer member 12, the degree of adhesion of the heat transfer member 12 to the conductor members C1 and the conductor grooves 112 at the above-mentioned locations can be increased, thereby further improving the cooling efficiency.

It should be noted that the embodiments explained above merely show representative forms of the conductor cooling structure. The conductor cooling structure is not limited thereto and can be modified in various ways.

For example, the embodiment explained above shows, as an example of the conductor cooling structure, the conductor cooling structure 1 for cooling the conductor members C1 connected to the relay, i.e., the electric/electronic component E1. However, the conductor cooling structure is not limited thereto, and the cooling target may be conductor members connected to an electric component other than a relay, or may be a conductor members connected to other electronic components.

Furthermore, the embodiment explained above shows, as an example of the conductor cooling structure, the conductor cooling structure 1 with the pair of conductor grooves 112 provided in the cooling plate 11 in one-to-one correspondence with the pair of conductor members C1 connected to the electric/electronic component E1. However, the conductor cooling structure is not limited thereto, and may have one conductor member connected to an electric/electronic component, and only one conductor groove provided in the cooling plate in one-to-one correspondence with the conductor member. Alternatively, three or more conductor members may be connected to an electric/electronic component, and multiple conductor grooves may be provided in one-to-one correspondence with the multiple conductor members.

Furthermore, the embodiment explained above shows, as an example of the conductor cooling structure, the conductor cooling structure 1 including the conductor grooves 112 formed as a corner groove in an L shape in the cooling plate 11 corresponding to the conductor members C1 formed in the shape of a band plate in an L shape. However, the conductor cooling structure is not limited thereto, and the shape of the conductor members of the cooling target may be any shape other than L shape as long as it is a band plate shape, and the conductor grooves provided in the cooling plate may also be formed into a shape other than L shape depending on the shape of the conductor members. Furthermore, the conductor grooves are not limited to square grooves, and may be polygonal grooves other than a rectangle, a round groove, and the like, as long as the conductor grooves have a depth sufficient to contain the conductor members in at least a part of its thickness direction.

Furthermore, the embodiment explained above shows, as an example of the heat transfer member, the heat transfer member 12 made of, for example, a heat transfer sheet such as Tflex SF600 Series (registered trademark) of Laird. However, the heat transfer member is not limited thereto, and any material may be used as long as it is formed from an insulating material that is sandwiched between the groove inner surfaces of the conductor grooves and the conductor members and transfers heat from the conductor members to the cooling plate.

Furthermore, the embodiment explained above shows, as an example of the conductor groove, the conductor grooves 112 that are wider than conductor members C1 by the thickness of the heat transfer member 12. However, the conductor grooves are not limited thereto, and any groove width may be adopted as long as the conductor grooves are formed along the length directions of the conductor members in the band plate shape and can accommodate at least portions of the conductor members in the thickness direction. However, as described above, according to the conductor grooves 112 that are wider than the conductor members C1 by an amount corresponding to the thickness of the heat transfer member 12, heat can be effectively transferred via the heat transfer member 12, so that the cooling efficiency can be further improved.

Furthermore, the embodiment explained above shows, as an example of the heat transfer member, the heat transfer member 12 that is disposed to cover the entire surface of the front surface 111 of the cooling plate 11. However, the heat transfer member is not limited thereto, and may be, for example, a conductor member or a member processed into a shape corresponding to the shape of the conductor grooves, as long as it covers a wider area than the conductor grooves on the front surface of the cooling plate. However, as described above, according to the heat transfer member 12 arranged to cover the entire surface of the front surface 111 of the cooling plate 11, fine shape processing is not required for the heat transfer member 12, and the manufacturing cost can be reduced.

Furthermore, the embodiment explained above shows, as an example of the conductor cooling structure, the conductor cooling structure 1 in which the component fixing studs 113 are vertically provided on the front surface 111 of the cooling plate 11, and the stud through holes 121 are provided in the heat transfer member 12. However, the conductor cooling structure is not limited thereto, and the way how the electric/electronic component is mounted to the cooling plate is not particularly limited, and the heat transfer member can be formed in various shapes that do not hinder the mounting. However, as described above, when the electric/electronic component E1 is mounted to the cooling plate 11 via the component fixing studs 113, and adopting the heat transfer member 12 shaped to avoid the component fixing studs 113, the manufacturing cost can be reduced.

Furthermore, the embodiment explained above shows, as an example of the heat transfer member, the heat transfer member 12 that is made of the flexible sheet material and that, when the conductor members C1 are pressed against the conductor grooves 112, is crushed and comes into close contact with various parts of the groove inner surfaces 112a of the conductor grooves 112 and various parts of the conductor members. However, the heat transfer member is not limited thereto, and may be, for example, a hard resin formed into a shape corresponding to the inner surface shapes of the conductor grooves and the outer surface shapes of the conductor members. However, as described above, when the heat transfer member 12 is made of the flexible sheet material and the conductor members C1 are pressed to crush the heat transfer member 12 and bring the heat transfer member 12 into close contact with the above-mentioned locations, the cooling efficiency can be further improved.

### LIST OF REFERENCE SIGNS

1 conductor cooling structure
11 cooling plate
12 heat transfer member
111 front surface
112 conductor groove
112a groove inner surface
112a-1 groove bottom surface
112a-2 groove side surface
113 component fixing stud
113a screw hole
121 stud through hole
C1 conductor member
C11 groove opposing surface
C12 side edge surface
D11 longitudinal direction
D12 thickness direction
D13 member thickness direction
E1 electric/electronic component
E11 component terminal
E12 fixing flange
E13 screw

What is claimed is:

1. A conductor cooling structure comprising:
a cooling plate formed into a band plate shape made of a conductive metal and being a flat plate-shaped member configured to cool a conductor member with a predetermined electric/electronic component being fixed to a front surface of the cooling plate in such a state that the conductor member is placed on the front surface of the cooling plate, the conductor member configured to be energized with one end side of the conductor member being connected to a component terminal of the electric/electronic component, and the other end side of the conductor member being connected to an electrical connection target of the electric/electronic component, a conductor groove being formed on the front surface of the cooling plate, the conductor groove extending along a shape of a longitudinal direction of the conductor member and formed to have a sufficient depth to accommodate at least a portion of the conductor member in a thickness direction thereof; and
a heat transfer member covering an area larger than at least the conductor groove on the front surface of the cooling plate so as to be sandwiched between a groove inner surface of the conductor groove and the conductor member, the heat transfer member being made of an insulating material that transfers heat of the conductor member to the cooling plate.

2. The conductor cooling structure according to claim 1, wherein the conductor groove is a groove that is wider than the conductor member by an amount of a thickness of the heat transfer member.

3. The conductor cooling structure according to claim 1, wherein the heat transfer member is arranged to cover an entire surface of the front surface of the cooling plate.

4. The conductor cooling structure according to claim 3, wherein a component fixing stud is provided vertically on the front surface of the cooling plate, the electric/electronic component having the component terminal connected to the conductor member is fixed to the component fixing stud so as to press the conductor member against the conductor groove with the heat transfer member being sandwiched between the groove inner surface and the conductor member, and
the heat transfer member is provided with a stud through hole through which the component fixing stud penetrates.

5. The conductor cooling structure according to claim 1, wherein the heat transfer member is a flexible sheet material that, when the conductor member is pressed against the conductor groove, is crushed in a member thickness direction of the heat transfer member and comes into close contact with both a groove bottom surface of the groove inner surface and a groove opposing surface, facing the groove bottom surface, of front and back surfaces of the conductor member, and also with both groove side surfaces of the groove inner surface and side edge surfaces, extending in the thickness direction, of the conductor member.
